(19) United States
(12) Patent Application Publication
(10) Pub. No.: US 2026/0342338 A1
(43) Pub. Date: Oct. 29, 2026

(54) FREQUENCY PREDICTOR AND METHOD FOR PREDICTING OUTPUT FREQUENCY

(71) Applicant: Nuvoton Technology Corporation, Hsinchu Science Park (TW)

(72) Inventors: Chih-Hung HUANG, Hsinchu Science Park (TW); Hao-Yang CHANG, Hsinchu Science Park (TW)

(21) Appl. No.: 19/647,062

(22) Filed: Apr. 14, 2026

(30) Foreign Application Priority Data
Apr. 23, 2025 (TW) 114115342

(51) Int. Cl. H03L 1/02; H03L 7/083

(52) U.S. Cl. CPC H03L 1/022; H03L 7/083

(57) ABSTRACT

A frequency predictor is provided for adjusting the output frequency of a phase locked loop (PLL) of an electronic system. The frequency predictor includes an intelligent unit that performs the following operations. With reference to the PLL frequency-parameter correspondence, the PLL parameter value required by the phase-locked loop is set according to the target output frequency. With reference to the frequency deviation-temperature correspondence, the PLL parameter value is adjusted according to the local temperature of the electronic system. With reference to the temperature-loading amount correspondence, the future temperature is predicted according to the loading amount of at least one loading source of the electronic system, and the PLL parameter value is adjusted according to the future temperature so that the phase-locked loop outputs a predicted frequency to reflect the change in the load of the electronic system.

### CROSS REFERENCE TO RELATED APPLICATIONS

This Application claims priority of Taiwan Patent Application No. 114115342, filed on Apr. 23, 2025, the entirety of which is incorporated by reference herein.

### BACKGROUND OF THE INVENTION

### Field of the Invention

The present invention relates to an electronic system with a phase-locked loop (PLL), and more particularly to a frequency predictor and method for predicting output frequency for adjusting the output frequency of the phase-locked loop in the electronic system.

### Description of the Related Art

A System on Chip (SoC) is a technology in which various functional modules of an entire system are integrated into a single chip. The SoC integrates multi-function components into the single chip, such that the electronic device (such as smart phone, embedded system, wearable devices, etc.) is lightweight, energy-efficient, and high-performance. The advantages of the SoC include cost reduction, minimal space requirement, and energy-efficiency improvement.

Generally, SoCs typically have an internal adjustable phase-locked loop (PLL). Although the target frequency of the PLL can be pre-adjusted by a testing machine before factory shipment, during actual operation after factory shipment, the temperature of the electronic system may change due to different system loads, causing the target frequency of the PLL to deviate. Some types of SoCs require stable and accurate clock frequencies to ensure proper function and operation, such as the Baud rate of UART (Universal Asynchronous Receiver/Transmitter) and the eye pattern of USB (Universal Serial Bus).

SoCs often have some fixed clock sources, such as: SPI (Serial Peripheral Interface) clock, eSPI (Enhanced Serial Peripheral Interface) clock, LPC (Low Pin Count) clock, Ethernet clock, etc. If the frequencies corresponding to the above-mentioned clock sources are known in advance, they can be provided to computing devices such as processors and controllers to verify the output frequency of the phase-locked loop and continuously modify or learn, so that the output frequency of the phase-locked loop can become more stable and accurate.

### BRIEF SUMMARY OF THE INVENTION

Accordingly, the present invention provides a frequency predictor and a method for predicting the output frequency, which predicts the future temperature of the electronic system by referring to the change of the loading source of the electronic system, and adjusts the parameters used to control the output frequency of the phase-locked loop in advance based on the future temperature, so that the output frequency of the phase-locked loop tends to be stable and accurate.

An embodiment of the present invention provides a frequency predictor for adjusting the output frequency of a phase-locked loop in an electronic system. The frequency predictor includes an intelligent unit which is configured to perform the following operations. With reference to the PLL frequency-parameter correspondence, the intelligent unit sets the required PLL parameter value for the phase-locked loop based on the target output frequency. With reference to the frequency deviation-temperature correspondence, the intelligent unit adjusts the PLL parameter value based on the local temperature of the electronic system. In addition, with reference to the temperature-loading amount correspondence, the intelligent unit predicts the future temperature according to the loading amount of at least one loading source of the electronic system, and adjusting the PLL parameter value according to the future temperature so that the phase-locked loop outputs a predicted frequency to reflect the change in the loading amount of the electronic system.

In some aspects of this embodiment, the intelligent unit further performs the following operations: obtaining the frequency of at least one clock input source in the electronic system as a first reference frequency; and verifying, based on the first reference frequency, whether the predicted frequency output by the phase-locked loop based on the PLL parameter value conforms to the target output frequency.

In some aspects of this embodiment, the intelligent unit further performs the following operation: generating the temperature-loading amount correspondence based on the load amount of the electronic system from the past to the present and the local temperature.

In some aspects of this embodiment, the frequency predictor further includes a database configured to store the PLL frequency-parameter correspondence, the frequency deviation-temperature correspondence, the target output frequency, and the frequency of the clock input source.

In some aspects of this embodiment, the intelligent unit further performs the following operations. The PLL frequency-parameter correspondence and the frequency deviation-temperature correspondence are read from the database. The PLL frequency-parameter correspondence is corrected based on the PLL parameter value and the predicted frequency. The frequency deviation-temperature correspondence is corrected based on the deviation between the predicted frequency and the target output frequency, and the future temperature.

In some aspects of this embodiment, the intelligent unit receives the local temperature from the temperature sensor of the electronic system.

In some aspects of this embodiment, the microcontroller unit of the electronic system is configured to monitor the loading amount of the loading source and transmit the loading amount to the intelligent unit.

In some aspects of this embodiment, when the clock input source providing the first reference frequency stops outputting, the intelligent unit uses the frequency of another clock input source of the electronic system as a second reference frequency to verify the predicted frequency.

In some aspects of this embodiment, the intelligent unit is a programmable device configured to perform calculation, processing, and control tasks.

Another embodiment of the present invention provides a method for predicting an output frequency for adjusting an output frequency of a phase-locked loop in an electronic system. The method includes the following steps, which are performed by an intelligent unit of a frequency predictor. With reference to the PLL frequency-parameter correspondence, the required PLL parameter value for the phase-locked loop is set, based on a target output frequency. With reference to the frequency deviation-temperature correspondence, the PLL parameter value is adjusted based on the local temperature of the electronic system. With reference to the temperature-loading amount correspondence, the future temperature is predicted based on the loading amount of at least one loading source of the electronic system, and the PLL parameter value is adjusted based on the future temperature so that the phase-locked loop outputs a predicted frequency to reflect a change in the loading amount of the electronic system.

In some aspects of this embodiment, the method further includes the steps of obtaining the frequency of at least one clock input source in the electronic system as a first reference frequency; and verifying, based on the first reference frequency, whether the predicted frequency output by the phase-locked loop based on the PLL parameter value conforms to the target output frequency.

In some aspects of this embodiment, the method further includes the step of generating the temperature-loading amount correspondence based on the loading amount of the electronic system from the past to the present and the local temperature.

In some aspects of this embodiment, the method further includes the step of correcting the PLL frequency-parameter correspondence based on the PLL parameter value and the predicted frequency; and correcting the frequency deviation-temperature correspondence based on the deviation between the predicted frequency and the target frequency, and the future temperature.

### BRIEF DESCRIPTION OF THE DRAWINGS

The present invention can be more fully understood by reading the subsequent detailed description and examples with references made to the accompanying drawings, wherein:

FIG. 1 illustrates an exemplary structure of an electronic system 10 having a phase-locked loop 101.

FIG. 2 illustrates an exemplary configuration of a frequency predictor 102 according to an embodiment of the present invention.

### DETAILED DESCRIPTION OF THE INVENTION

To make the above-mentioned objects, features, and advantages of the present invention more apparent and understandable, preferred embodiments are described below in detail with reference to the accompanying drawings.

The frequency predictor of the present invention performs a method for predicting the output frequency, for adjusting the output frequency of a phase-locked loop (hereinafter, sometimes may referred to as PLL) in an electronic system.

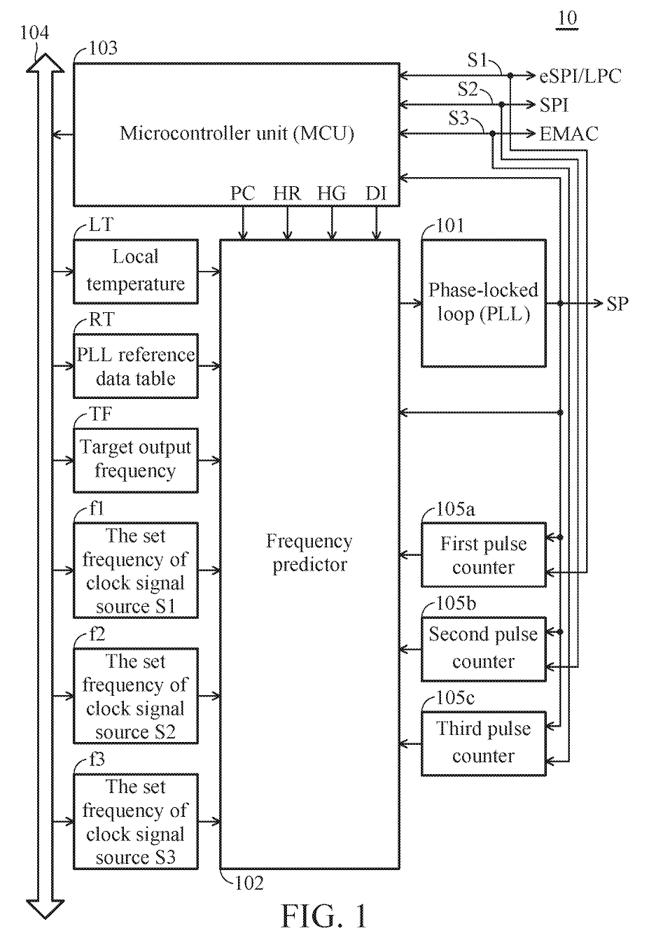

FIG. 1 shows an exemplary structure of an electronic system 10 having a phase-locked loop 101. In this electronic system 10, the frequency predictor 102 performs a method for predicting the output frequency, thereby adjusting the output frequency of the phase-locked loop 101 in the electronic system 10.

In FIG. 1, the electronic system 10, for example but not limited thereto, includes a phase-locked loop 101, a frequency predictor 102, and a microcontroller unit (MCU) 103.

The microcontroller unit 103 is connected to multiple clock signal sources. Here, for example but not limited to, multiple clock signal sources include the eSPI/LPC clock, the SPI clock, and the EMAC (Ethernet Media Access Control) clock. In addition, the microcontroller unit 103 also receives the clock (frequency) SP output from the phase-locked loop 101.

The microcontroller unit 103 executes pre-assigned operations according to the eSPI/LPC clock, SPI clock, and EMAC clock. During operations, the microcontroller unit 103 simultaneously monitors the loading amount (load status) corresponding to multiple loading sources of the electronic system 10. Here, the loading sources include, for example, the program count (PC), cache hit rate (HR), host grant (HG), and the number of device interrupt request (DI), but are not limited to these. These loading sources (PC, HR, HG, DI) are related to the operational busyness of the electronic system 10, and each or in combination, may affect the local temperature (LT) of the electronic system 10. The microcontroller unit 103 transmits the loading amount (L1~L4) of the above-mentioned loading sources (program count PC, cache hit rate HR, host grant (HG), and the number of device interrupt request (DI)) to the frequency predictor 102.

The frequency predictor 102 receives the local temperature LT of the electronic system 10, the PLL reference data table RT, the target output frequency TF of the phase-locked loop 101, and the set frequencies f1 to fN of one or more (the first to Nth) clock signal sources (S1 to SN). For brevity in the FIG. 1, it is assumed that N equals 3, but it is not limited to this. In addition, the first clock signal source S1 to the third clock signal source S3 are, for example, the above-mentioned eSPI/LPC clock, SPI clock, and EMAC clock, respectively. In this embodiment, the electronic system 10 has, for example, a temperature sensor (not shown) that obtains the local temperature LT of the electronic system 10 and transmits it to the frequency predictor 102. In addition, the PLL reference data table RT, the target output frequency TF, and the set frequencies f1 to f3 of the first clock signal source S1 to the third clock signal source S3 can be transmitted to the frequency predictor 102 by the microcontroller unit 103 through the internal bus 104 of the electronic system 10.

In addition, the electronic system 10 has three (N) pulse counters to count the number of periodic pulses of the above-mentioned first to Nth clock signal sources S1 to SN, respectively. In this embodiment, N equals 3, and the electronic system 10 has a first pulse counter 105a, a second pulse counter 105b and a third pulse counter 105c. The first pulse counter 105a, the second pulse counter 105b and the third pulse counter 105c receive the first clock signal source S1 (eSPI/LPC clock), the second clock signal source S2 (SPI clock) and the third clock signal source S1 (EMAC clock), respectively, to obtain the number of pulses in each cycle. In addition, the first pulse counter 105a, the second pulse counter 105b and the third pulse counter 105c receive the clock SP output by the phase-locked loop 101 and obtain the number of pulses in each cycle of the clock SP output by the phase-locked loop 101. In addition, the frequency predictor 102 also receives the clock SP output by the phase-locked loop 101.

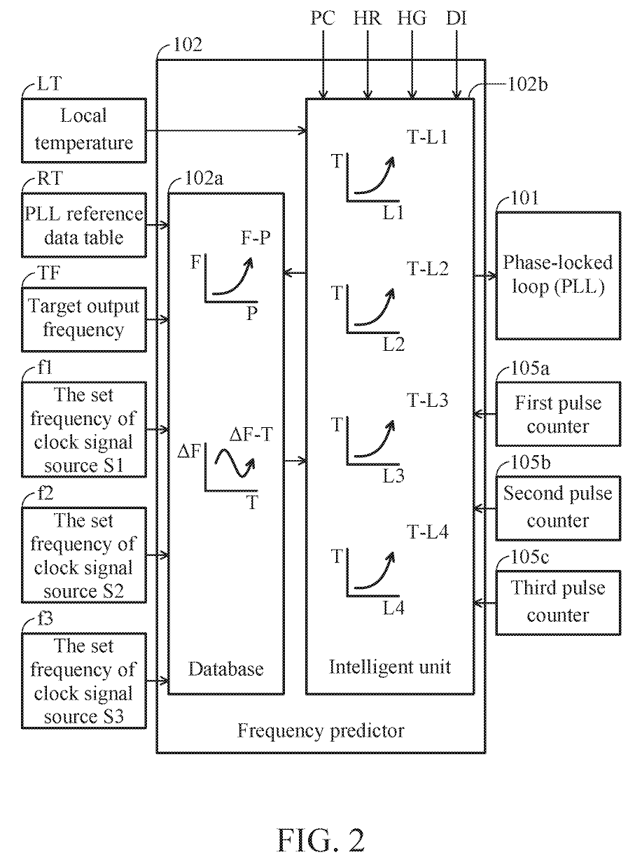

FIG. 2 illustrates an exemplary configuration of the frequency predictor 102 according to an embodiment of the present invention. Hereinafter, the operation of the frequency predictor 102 will be described with reference to FIG. 2.

As shown in FIG. 2, the frequency predictor 102 is configured with a database 102a and an intelligent unit 102b. The database 102a stores the PLL reference data table RT, the target output frequency TF of the phase-locked loop 101, and the set frequencies f1 to f3 of the first clock signal source S1 to the third clock signal source S3, which are received by the frequency predictor 102. Based on the PLL reference data table RT, the intelligent unit 102 can further organize the PLL frequency-parameter correspondence (FP), which can be recorded using a look-up table, a relationship curve, or an equation. Here, as shown in FIG. 2, the PLL frequency-parameter correspondence FP is presented as a "relationship curve (F-P) between frequency and PLL parameter," but it is not limited to this. The intelligent unit 102 can set the parameters required for the phase-locked loop 101 according to the target output frequency RT by using the PLL frequency-parameter correspondence FP.

The database 102a also stores the frequency deviation-temperature correspondence (DT), which can be recorded using a reference table, a relationship curve, or an equation. Here, as shown in FIG. 2, the frequency deviation-temperature correspondence is presented as a "relationship curve (ΔF-T) between deviation and temperature." Based on this frequency deviation-temperature correspondence DT and the local temperature (LT) of the electronic system 10, the intelligent unit 102b can determine the frequency deviation (ΔF) between the output frequency of the phase-locked loop 101 and the target output frequency (TF) when affected by temperature. It should be noted that the data related to this frequency deviation-temperature correspondence (DT) can be obtained by the manufacturer through actual measurement, for example, by recording the deviation between the actual output frequency and the target output frequency and their correspondence in advance for the phase-locked loop operating at different temperatures. In the operation described later, the intelligent unit 102b can continuously modify this the frequency deviation-temperature correspondence (DT) based on changes in the local temperature (LT) and the actual frequency output of the phase-locked loop 101.

In some aspects of this embodiment, the intelligent unit 102b, for example but not limited to, is a programmable device that includes computing ability and logic control function and can be loaded with a program to perform tasks of calculation, processing, and control. In this embodiment, the intelligent unit 102b may be implemented, for example, by a microprocessor, microcontroller, digital signal processor (DSP), field-programmable gate array (FPGA), and embedded device, but is not limited thereto.

In some embodiments, the intelligent unit 102b loads a program to perform a method for predicting the output frequency to adjust the output frequency SP of the phase-locked loop 101 of the electronic system 10. To be specific, the intelligent unit 102b performs the following operations.

The intelligent unit 102b, with reference to the PLL frequency-parameter correspondence FP and based on the target output frequency TF, sets the required PLL parameter value PV for the phase-locked loop 101. For example, if the target output frequency TF received by the intelligent unit 102 is 20MHz, then by referring to the PLL frequency-parameter correspondence FP, the PLL parameter value PV (for example, a value represented by multiple bits) corresponding to this target output frequency is found and output to the phase-locked loop 101.

The intelligent unit 102b further refers to the frequency deviation-temperature correspondence DT, and adjusts the PLL parameter value PV based on the received local temperature LT of the electronic system 10. Since the local temperature LT affects the output frequency SP of the phase-locked loop 101, the intelligent unit 102b further adjusts the required PLL parameter value PV of the phase-locked loop 101 based on the local temperature LT. To be more specific, the intelligent unit 102b obtains the frequency deviation (ΔF) caused by the local temperature LT based on the frequency deviation-temperature correspondence DT, and uses the frequency deviation (ΔF) in conjunction with the PLL reference data table RT to further adjust the required PLL parameter value PV of the phase-locked loop 101.

The frequency predictor 102 receives the loading data (loading amount) L1 to L4 from different loading sources (such as program counter PC, cache hit rate HR, host grant HG, and the number of device interrupt request DI) from the microcontroller unit 103. The frequency predictor 102 can generate corresponding equations or curves based on temperature and loading amount L1 to L4. In FIG. 2, the frequency predictor 102, for example, generates curves of temperature relative to program counter PC, cache hit rate HR, host grant HG, and the number of device interrupt request DI, namely, curves T-L1, T-L2, T-L3, and T-L4. In addition, equations or curves (temperature-load amount correspondence, i.e., relationship between temperature and loading amount) generated based on previously experimented and recorded past local temperatures and past loading amount (loading data) can be provided to the intelligent unit 102b as initial values.

Therefore, when the loading amount of the loading sources of the electronic system 10 (program counter PC, cache hit rate HR, host grant HG, or the number of device interrupt request DI) increases or decreases, the intelligent device 102b can use an equation or curve corresponding to a single loading source and temperature (for example, the T-L1 curve), or a combination of equations or curves corresponding to multiple loading sources and temperature (for example, T-L1 to T-L4 curves), to predict the temperature change caused by the load change, thereby predicting the future temperature. The intelligent device 102b, using the future temperature and in conjunction with the above-mentioned frequency deviation-temperature correspondence DT, adjusts the PLL parameter value PV to be set for the phase-locked loop 101 in advance, so that the above-mentioned phase-locked loop 101 outputs a predicted frequency to reflect the load change of the electronic system 10. Therefore, even if the local temperature LT changes due to variations in the loading amount of the electronic system 10 in the future, the frequency generated by the phase-locked loop 101 will tend to be stable and accurate because the PLL parameter value PV of the phase-locked loop 101 has been pre-adjusted by the intelligent unit 102b. Here, the combined use of equations or curves corresponding to multiple loading sources and temperatures represents various operational combinations performed on the components corresponding to multiple temperature loading amount, such as linear combinations of the T-L1, T-L2, T-L3, and T-L4 curves, but is not limited to this.

Referring to FIG. 1 and FIG. 2, the first pulse counter 105a, the second pulse counter 105b, and the third pulse counter 105c count the number of pulses in each cycle of the eSPI/LPC clock source (S1), the SPI clock source (S2), and the EMAC clock source (S3), respectively. The first pulse counter 105a, the second pulse counter 105b, and the third pulse counter 105c simultaneously count the pulses of the clock SP output by the phase-locked loop 101 to obtain the number of pulses in each cycle. The first pulse counter 105a, the second pulse counter 105b, and the third pulse counter 105c output the pulse counting results to the intelligent unit 102b.

Subsequently, the intelligent unit 102b reads the target frequency TF from the database 102a, and the frequencies of the eSPI/LPC clock source (S1), the SPI clock source (S2), or the EMAC clock source (S3). The intelligent unit 102b then compares, for example, the ratio of the SPI clock source frequency to the target frequency TF, and the ratio of the pulse count value of the SPI clock source (S1) to the pulse count value of the output clock (SP) of the phase-locked loop 101, to verify whether the output frequency of the phase-locked loop 101 is correct.

Since the pulse count results of the first to third pulse counters (105a~105c) require time to process (for example, one clock cycle), the pulse count results can be provided to the intelligent unit 102b to verify the past output frequency of the phase-locked loop 101 (also called past frequency results). The intelligent unit 102b can use this past frequency results to verify whether the parameter previously given to the phase-locked loop 101 is correct, thereby correcting the PLL frequency-parameter correspondence FP in the database 102a. Similarly, the intelligent unit 102b can use the past frequency results to verify whether the frequency deviation is correct when the temperature changes, thereby correcting the frequency deviation-temperature correspondence DT in the database 102a.

Generally, the results of the pulse counting of multiple clock input sources (eSPI/LPC, SPI, EMAC) S1~S3 can be provided to the intelligent unit 102b for verification. However, if a clock input source that is not fixed and continuously input, such as eSPI_CLK (the clock input source of the eSPI bus), is used for verification, the intelligent unit 102b will dynamically adjust whether to include this input source for verification. Assuming it has been incorporated for the verification, when the clock input source (eSPI_CLK) stops inputting, the intelligent unit 101 will receive a significantly abnormal pulse counter result through the pulse counter. The intelligent unit 101 will then refer to the pulse count results of other clock input sources, such as the signal sources S1, S2, or S3, and exclude the pulse count result of the eSPI_CLK clock input source. When the eSPI_CLK clock input source resumes inputting, the intelligent unit 101 will receive a more reasonable pulse count result and will then include the pulse count result of this clock input source for the verification again.

As described above, the intelligent unit 101 can correct the frequency deviation-temperature correspondence DT in the database 102a. Therefore, the intelligent unit 101 can modify or learn the equation or curve (for example, T-L1, T-L2, T-L3, and T-L4) corresponding to the loading amount of the loading source based on the current local temperature LT, the past local temperatures, and the load changes, making the temperature prediction more accurate when the loading amount of the loading source changes. Since the intelligent unit 101 can continuously improve the accuracy of temperature prediction when the loading amount changes, when adjusting the PLL parameter value PV of the phase-locked loop 101 in response to loading amount and temperature changes, it can adjust the parameters to well match the future temperature of the electronic system 10, making the frequency generated by the phase-locked loop 101 more stable and accurate.

According to the disclosure of the present invention, the following features are present.
(1) The intelligent unit in the frequency predictor of the present invention can predict the future temperature of the electronic system by referring to changes in various loading sources and pre-adjust the PLL parameter value to be provided to the phase-locked loop, making the frequency generated by the phase-locked loop more stable and accurate.
(2) The frequency predictor of the present invention uses pulse counters to count the output clocks of the phase-locked loop and various clock input sources and then feeds the count results back to the intelligent unit to verify and correct the data in the database.
(3) The frequency predictor of the present invention can also determine, through the intelligent unit, whether to incorporate a clock input source that is not fixed and continuously input, in the verification process.
(4) The intelligent unit in the frequency predictor of the present invention improves and learns the equation or curve of temperature corresponding to the loading amount of the loading source based on the current local temperature, the past local temperatures, and the loading amount changes, making temperature prediction more accurate, thereby improving parameter adjustment and making the frequency generated by the PLL more stable and accurate.

Although the present invention has been disclosed above by way of embodiments, it is not intended to limit the present invention. Any person skilled in the art can make various modifications and refinements without departing from the spirit and scope of the present invention. Therefore, the scope of protection of the present invention shall be determined by the appended claims.

What is claimed is:

1. A frequency predictor for adjusting the output frequency of a phase-locked loop (PLL) of an electronic system, comprising:
an intelligent unit configured to perform the following operations:
with reference to a PLL frequency-parameter correspondence, setting a required PLL parameter value for the phase-locked loop based on a target output frequency;
with reference to a frequency deviation-temperature correspondence, adjusting the PLL parameter value based on a local temperature of the electronic system; and
with reference to a temperature-loading amount correspondence, predicting a future temperature according to the loading amount of at least one loading source of the electronic system, and adjusting the PLL parameter value according to the future temperature so that the phase-locked loop outputs a predicted frequency to reflect a change in the loading amount of the electronic system.

2. The frequency predictor as claimed in claim 1, wherein the intelligent unit further performs the following operations:
obtaining the frequency of at least one clock input source in the electronic system as a first reference frequency; and
verifying, based on the first reference frequency, whether the predicted frequency output by the phase-locked loop based on the PLL parameter value conforms to the target output frequency.

3. The frequency predictor as claimed in claim 2, wherein the intelligent unit further performs the following operation:
generating the temperature-loading amount correspondence based on the load amount of the electronic system from the past to the present and the local temperature.

4. The frequency predictor as claimed in claim 2, further comprising:
a database configured to store the PLL frequency-parameter correspondence, the frequency deviation-temperature correspondence, the target output frequency, and the frequency of the clock input source.

5. The frequency predictor as claimed in claim 4, wherein the intelligent unit further performs the following operations:
Reading, from the database, the PLL frequency-parameter correspondence and the frequency deviation-temperature correspondence;
modifying the PLL frequency-parameter correspondence based on the PLL parameter value and the predicted frequency; and
modifying the frequency deviation-temperature correspondence based on a deviation between the predicted frequency and the target output frequency, and the future temperature.

6. The frequency predictor as claimed in claim 1, wherein the intelligent unit receives the local temperature from a temperature sensor of the electronic system.

7. The frequency predictor as claimed in claim 6, wherein a microcontroller unit of the electronic system is configured to monitor the loading amount of the loading source and transmit the loading amount to the intelligent unit.

8. The frequency predictor as claimed in claim 2, wherein when the clock input source providing the first reference frequency stops outputting, the intelligent unit uses the frequency of another clock input source of the electronic system as a second reference frequency to verify the predicted frequency.

9. The frequency predictor as claimed in claim 1, wherein the intelligent unit is a programmable device configured to perform calculation, processing, and control tasks.

10. A method for predicting an output frequency, for adjusting an output frequency of a phase-locked loop (PLL) of an electronic system, the method comprising:
with reference to a PLL frequency-parameter correspondence, setting a required PLL parameter value for the phase-locked loop based on a target output frequency;
with reference to a frequency deviation-temperature correspondence, adjusting the PLL parameter value based on a local temperature of the electronic system;
with reference to a temperature-loading amount correspondence, predicting a future temperature based on a loading amount of at least one loading source of the electronic system, and adjusting the PLL parameter value based on the future temperature so that the phase-locked loop outputs a predicted frequency to reflect a change in the loading amount of the electronic system.

11. The method for predicting the output frequency as claimed in claim 10, further comprising:
obtaining the frequency of at least one clock input source in the electronic system as a first reference frequency; and
verifying, based on the first reference frequency, whether the predicted frequency output by the phase-locked loop based on the PLL parameter value conforms to the target output frequency.

12. The method for predicting the output frequency as claimed in claim 11, further comprising:
generating the temperature-loading amount correspondence based on the loading amount of the electronic system from the past to the present and the local temperature.

13. The method for predicting the output frequency as claimed in claim 11 further comprising:
modifying the PLL frequency-parameter correspondence based on the PLL parameter value and the predicted frequency; and
modifying the frequency deviation-temperature correspondence based on the deviation between the predicted frequency and the target frequency, and the future temperature.
